(19) United States
(12) Patent Application Publication
(10) Pub. No.: US 2014/0266463 A1
(43) Pub. Date: Sep. 18, 2014

(54) LINEAR AMPLIFIER ARRANGEMENT FOR HIGH-FREQUENCY SIGNALS

(71) Applicants: Ahmed Aref, Herzogenrath (DE); Renato Negra, Aachen (DE)

(72) Inventors: Ahmed Aref, Herzogenrath (DE); Renato Negra, Aachen (DE)

(73) Assignee: RWTH AACHEN, Aachen (DE)

(21) Appl. No.: 14/112,346

(22) PCT Filed: Apr. 20, 2012
(86) PCT No.: PCT/EP12/57270

§ 371 Date: Jun. 4, 2014

(30) Foreign Application Priority Data
Apr. 21, 2011 (DE) 10 2011 002 238.4

(51) Int. Cl. H03F 3/68; H03F 3/21; H03F 3/19

(52) U.S. Cl. CPC H03F 3/68; H03F 3/19; H03F 3/211; H03F 2200/39; H03F 2203/21106
USPC 330/295

(57) ABSTRACT

The invention relates to an amplifier arrangement for high-frequency signals. Said amplifier arrangement comprises a signal input (IN) for receiving high-frequency signals (RFᵢₙ) that are to be amplified, a first amplifier device (Mn₁, Mn₂) that amplifies the high-frequency signals that are to be amplified, the first amplifier device having a drain circuit, a source follower circuit or a similar device, an additional amplifier device (GB; Mn₃, Mn₄, Mn₅, M₆) which is arranged in parallel to the first amplifier device (Mn₁, Mn₂2) and amplifies the high-frequency signals that are to be amplified, and a signal output (OUT) for outputting the high-frequency signals (RFₒᵤₜ) amplified by the first and the additional amplifier device (GB; Mn₃, Mn₄, Mn₅, Mn₆).

The invention relates to an amplifier arrangement for high-frequency signals.

Amplifier arrangements for high-frequency signals (radio frequency RF) are also often referred to as power amplifiers (RF PAs).

In many respects, these amplifier arrangements represent the most demanding circuits of today's transmitters, particularly in integrated transmitters.

Efficiency as well as linearity and low noise are the critical points here, and therefore factors that must be considered individually or as a group.

Particularly in (broadband) wireless communication systems such as, for example, 3^{rd} and 4^{th} generation mobile systems, these demands pose enormous problems for the design of amplifier arrangements.

A longstanding area of research has emerged from this, the aim of which is to provide an integrated amplifier arrangement within an integrated transmitter. This area of research has been driven by the incomparable possibilities of the integration of digital, analog and high-frequency components in CMOS technology.

For several reasons, however, CMOS technology has been unable to tap the area of amplifier arrangements for high-frequency signals.

For one, the reliability of CMOS-based high-frequency amplifier arrangements is not always a given. One factor for this is the limited breakdown voltage of CMOS transistors.

For another, the linearity of CMOS-based high-frequency amplifier arrangements is not always a given, so that use thereof for broadband transmission systems is usually possible only to a very limited extent.

Nonetheless, it would be desirable to be able to offer high-frequency amplifier arrangements in this technology as well, since the manufacturing process is well controlled and versatile. Furthermore, cost-effective production is also possible.

In addition, a CMOS-based high-frequency amplifier arrangement would also offer additional possibilities that would not be possible with III-V technology, or only at great expense.

This includes the possibility of so-called on-chip calibration, which could be associated with the amplifier arrangement, thus making it possible to influence the amplifier arrangement in order to influence the performance data.

Moreover, in CMOS technology, a fully integrated transmitter could also be manufactured on a single chip.

Previous efforts in this area were thereby characterized in that one of these demands was essentially optimized at the expense of the other demands.

For example, improvements through so-called distributed active transformers (DAT) were attempted by distribution of the voltage load. In doing so, however, a mismatch of the different amplifiers arose as a matter of principle.

However, the efficiency that can be achieved is rather small, and the linearity is low as well unless substantial effort and expense is incurred.

While the linearity could be improved through the use of special signal processing for AM-FM phase distortion suppression, such a measure is very complex and costly.

Other approaches provide for an arrangement with several amplifiers. However, this approach is not preferred either, because it comes at the expense of the effectiveness and linearity.

Yet other approaches that pursue an architecture based on a common-source topology require highly specialized components, particularly coils of the highest quality, that generally cannot be manufactured in an integrated manner.

This approach is therefore hardly feasible either, since high-quality inductivities always drive up costs, regardless of whether they are integrated or not. If the quality can only be achieved with external coils, the overall system becomes even more expensive, since a special enclosure is then usually also required. It should furthermore be noted for these approaches that the linearity is insufficient for broadband signals.

Driven by the advantages, attempts were made to resolve the previous limitations through innovative possibilities.

In doing so, the inventors were able to provide an innovative amplifier arrangement that is applicable not only in CMOS technology, but in a series of other technologies as well, and which meets the demands for efficiency, linearity and low noise.

The solution being provided is stated in claim 1. Additional embodiments of the invention are the subject of the dependent claims without however claiming to be exhaustive.

The invention will be explained in further detail below with reference to the drawings.

FIG. 1 shows a first embodiment of the invention,

FIG. 2 shows a modification of the first embodiment of the invention,

FIG. 3 shows a second embodiment of the invention,

FIG. 4 shows a modification of the second embodiment of the invention,

FIG. 5 shows an embodiment of a stabilization network, and

FIG. 6 shows another embodiment of a stabilization network for use in embodiments of the invention.

A first embodiment of the invention is illustrated in FIG. 1.

Here, the amplifier arrangement for high-frequency signals has a signal input IN for receiving high-frequency signals RF, to be amplified which can come from a suitable source.

Connected to the signal input IN is a first amplifier device Mn₁, Mn₂ which amplifies the high-frequency signals to be amplified.

Illustrated in FIGS. 1 and 2, in representation of other technologies, are MOS transistors Mn₁, Mn₂, without limiting the invention to this technology.

For example, the transistors can also be embodied as bipolar transistors or HBT or HEMT transistors or as amplifier tubes.

Depending on the technology used, this first amplifier device is connected as a drain circuit or as a source-follower circuit or as a comparable device.

Furthermore, another amplifier device GB is connected to the input IN. This is connected parallel to the first amplifier device Mn₁, Mn₂. This second amplifier device amplifies the high-frequency signals to be amplified as well.

Moreover, the amplifier arrangement also comprises a signal output OUT for outputting the high-frequency signals RFₒᵤₜ amplified by the first and the other amplifier device GB.

The invention thereby exploits the fact that the drain circuit of the transistors Mn₁, Mn₂ exhibits a high level of linearity. The drain circuit thereby limits the output voltage control range to the driving signal level which is given by RFᵢₙ.

The low amplification of the drain circuit is counteracted by the provision of a second amplifier device GB (Gain Booster).

For one, the linearity of the first amplification device is maintained this way, and for another, the gain is provided by the second amplification device.

Investigations have thereby shown that it [is possible] with this amplifier arrangement to amplify the 1 dB compression point of the amplifier arrangement such that the amplifier arrangement is capable of supplying (1 W) 30 dBm to the output line while still limiting the output voltage control range.

The second amplifier device GB is configured here such that it essentially provides the gain of the amplifier arrangement.

As a result, it is possible to use moderate voltage control ranges while still allowing high output power.

As a result of the capacitance that forms between the control electrode and the source at the first amplifier device, for example between gate and source if the transistor Mn₁, Mn₂ is a MOS transistor, a feedback is provided, thus ensuring the linear properties in an advantageous manner.

Moreover, additional stabilization capacitors can be provided that contribute to the additional stabilization of the first amplifier device by means of the Miller effect.

The input-side stabilization network SN illustrated in FIG. 1 can comprise, for example, a stabilizing capacitor C_{stab} (see FIG. 6), a stabilizing capacitor-resistor combination R_{stab} C_{stab} (see FIG. 5) between the signal input IN and the first amplifier device Mn₁, Mn₂ and/or the second amplifier device GB; Mn₃, Mn₄, Mn₅, Mn₆.

Moreover, FIG. 1 shows another load R_{Load} which is provided to represent an emitter (antenna).

In contrast to FIG. 1, the other amplifier device GB in FIG. 2 is provided as a source circuit Mn₃, Mn₄, Mn₅, Mn₆.

Illustrated in FIG. 2—representative of other technologies—are MOS transistors Mn₃, Mn₄, Mn₅, Mn₆ without limiting the invention to this technology.

For example, the transistors can also be provided as bipolar transistors or HBT or HEMT transistors or as amplifier tubes.

However, it is also readily possible to provide other circuits here, for example an emitter circuit and/or a basic circuit and/or a cascade and/or comparable device such as, for example, a transconductance amplifier.

Although the figures show special forms of MOS transistors for example, the drain circuit is composed of P-MOS transistors and the other amplifier device GB is composed of N-MOS transistors the invention is not limited to this.

The embodiments of the invention illustrated in FIGS. 1 and 2 represent a differential arrangement. The amplifier devices are thereby connected via a balun BN to the signal output OUT.

The balun BN also provides thereby potentially necessary load matching.

In contrast, FIGS. 3 and 4 show so-called “single-ended” circuits. These correspond to the arrangements in FIGS. 1 and 2.

The amplifier arrangement of FIGS. 3 and 4 provides on the output side a load matching network LN which may be necessary under some circumstances.

The presented amplifier arrangement can be manufactured especially easily on Si and/or Ge and/or SiGe:C. Simple integration into conventional CMOS technologies is hereby made possible and, as a result, even integrated transmitters with integrated amplifier arrangement can be realized.

Alternatively, the presented arrangement can also be implemented in known III-V systems such as, for example, GaAs or InP, or in [vacuum] tube technology.

The presented amplifier arrangement is especially suitable for broadband high-frequency signals, for example for 3^{rd} and 4^{th} generation mobile communication systems, since the amplifier arrangement makes it possible to provide linear amplification with suitable efficiency over wide frequency ranges, for example with carrier frequencies in the range from 50 MHz to 2700 MHz.

By virtue of the outstanding linearity properties of the presented amplifier arrangement, it is also excellently suited for use in the low-power range, i.e., the output power of the amplified high-frequency signals (RFₒᵤₜ) is 500 milliwatts or more.

The amplifier arrangement presented here will be known in the future as a class O amplifier.

1. An amplifier arrangement for high-frequency electrical signals, comprising
a signal input (IN) for receiving high-frequency signals (RFᵢₙ) to be amplified,
a first amplifier device (Mn₁, Mn₂) which amplifies the high-frequency signals to be amplified,
another amplifier device (GB; Mn₃, Mn₄, Mn₅, Mn₆) which is parallel to the first amplifier device (Mn₁ t Mn₂) and which amplifies the high-frequency signals to be amplified and which is not the same amplifier arrangement as the first amplifier device (Mn₁, Mn₂), and
a signal output (OUT) for outputting the high-frequency signals (RFₒᵤₜ) amplified by the first and the other amplifier device (GB; Mn₃, Mn₄, Mn₅, Mn₆).

2. The amplifier arrangement as set forth in claim 1, wherein the first amplifier device is a drain circuit or a source-follower circuit or an emitter follower or a comparable device.

3. The amplifier arrangement as set forth in claim 1, wherein the other amplifier device (GB; Mn₃, Mn₄, Mn₅, Mn₆) comprises a source circuit and/or a gate circuit and/or an emitter circuit and/or a basic circuit and/or a comparable device.

4. The amplifier arrangement as set forth in claim 1, wherein the other amplifier device (GB; Mn₃, Mn₄, Mn₅, Mn₆) comprises a transconductance amplifier and/or a cascode circuit and/or a comparable device.

5. The amplifier arrangement as set forth in claim 1, wherein the arrangement further comprises a stabilization measure (SN; C_{stab}; R_{stab}; C_{stab}) between the signal input (IN) and the first amplifier device (Mn₁, Mn₂) and/or between signal input (IN) and the input of the other amplifier devices (GB; Mn₃, Mn₄, Mnₛ, Mn₆).

6. The amplifier arrangement as set forth in claim 1, wherein the signal output (OUT) comprises a load matching network (LN).

7. The amplifier arrangement as set forth claim 1, wherein the amplifier arrangement is a differential arrangement.

8. The amplifier arrangement as set forth in claim 1, wherein the signal output (OUT) comprises a balun (BN).

9. The amplifier arrangement as set forth claim 1, wherein the amplifier arrangement is a single-ended arrangement.

10. The amplifier arrangement as set forth in claim 1, wherein the high-frequency signals (RFᵢₙ,) to be amplified have a frequency of 50 MHz or more, preferably 400 MHz or more, preferably 800 MHz or more, particularly 1800 MHz to 2700 MHz and more.

11. The amplifier arrangement as set forth in claim 1, wherein the output power of the amplified high-frequency signals (RFₒᵤₜ) is 500 milliwatts or more.
